(19) United States
(12) Patent Application Publication
(10) Pub. No.: US 2015/0048887 A1
(43) Pub. Date: Feb. 19, 2015

(54) AMPLIFIER CIRCUIT

(71) Applicants: Naoko Nitta, Tokyo (JP); Katsuya Kato, Tokyo (JP); Kenji Mukai, Tokyo (JP); Kenichi Horiguchi, Tokyo (JP); Morishige Hieda, Tokyo (JP); Kazutomi Mori, Tokyo (JP); Kazuya Yamamoto, Tokyo (JP)

(72) Inventors: Naoko Nitta, Tokyo (JP); Katsuya Kato, Tokyo (JP); Kenji Mukai, Tokyo (JP); Kenichi Horiguchi, Tokyo (JP); Morishige Hieda, Tokyo (JP); Kazutomi Mori, Tokyo (JP); Kazuya Yamamoto, Tokyo (JP)

(73) Assignee: Mitsubishi Electric Corporation, Tokyo (JP)

(21) Appl. No.: 14/387,726

(22) PCT Filed: Mar. 12, 2013
(86) PCT No.: PCT/JP2013/056794

§ 371 Date: Sep. 24, 2014

(30) Foreign Application Priority Data
Apr. 9, 2012 (JP) 2012-088479

(51) Int. Cl. H03F 1/02; H03F 3/193; H03F 3/21

(52) U.S. Cl. CPC H03F 1/0277; H03F 3/211; H03F 3/193; H03F 2200/421; H03F 2203/21139; H03F 2203/21175
USPC 330/279; 330/310; 330/295

(57) ABSTRACT

An amplifier circuit is configured in such a manner that the withstand voltage between the terminals of a FET 2 (withstand voltage B) is higher than the withstand voltage between the terminals of a FET 1 (withstand voltage A), and that the gate width of the FET 1 (Wg1) is narrower than the gate width of the FET 2 (Wg2). This makes it possible to increase the gain while maintaining high output power. The narrow gate width of the FET 1 (Wg1) connected to an input terminal 3 enables reducing the size of the cascode amplifier.

### TECHNICAL FIELD

The present invention relates to a small-sized high-gain cascode amplifier and an amplifier circuit.

### BACKGROUND ART

As for mobile communication terminals typified by cellular phones, wireless communications become popular, and the mobile communication terminals have a problem of further downsizing and long operating hours using a battery.

In these circumstances, as for transistors used for the mobile communication terminals also, it is considered very important to further downsize and improve efficiency of them.

Since cascode amplifiers that have two transistors connected in cascode have superior high-frequency characteristics, they are widely used.

FIG. 11 is a diagram showing a configuration of a common cascode amplifier.

The cascode amplifier of FIG. 11 has two FETs (Field-Effect Transistors) connected in cascode, and the two transistors 101 and 102 have the same withstand voltage between the terminals (withstand voltage A). In addition, the two transistors 101 and 102 have the same gate width (Wg1).

In the cascode amplifier, there is a possibility that a voltage exceeding the withstand voltage between the terminals (withstand voltage A) of the transistor 102 is applied to the drain terminal (collector terminal if the transistors 101 and 102 are a bipolar transistor) because of an instantaneous peak voltage occurring at the input of a modulating wave signal.

For this reason, it is conceivable to use high-voltage transistors as the transistors 101 and 102. In this case, however, since the gain reduces because of the reduction of the gate capacitance of the transistors 101 and 102, the performance of the amplifier deteriorates.

Thus, the following Patent Document 1 proposes a cascode amplifier comprising a transistor 101 and a transistor 102 connected in cascode, which transistors have different withstand voltages between the terminals (different gate oxide films).

FIG. 12 is a diagram showing a configuration of a cascode amplifier disclosed in the Patent Document 1.

In the cascode amplifier of FIG. 12, it is assumed that the withstand voltage between the terminals of the transistor 101 is withstand voltage A, and the withstand voltage between the terminals of the transistor 102 is withstand voltage B, and that the withstand voltage between the terminals of the transistor 102 is made higher than the withstand voltage between the terminals of the transistor 101 (withstand voltage A<withstand voltage B).

In the cascode amplifier of FIG. 12, the transistor 101 has its drain terminal connected to the source terminal of the transistor 102 to form a cascode connection, and its source terminal grounded.

The transistor 101 has its gate terminal connected to an input terminal 103 of the cascode amplifier and to a gate voltage terminal 104.

In addition, the transistor 102 has its drain terminal connected to a supply voltage terminal 105 via a DC feed inductor and to an output terminal 106 of the cascode amplifier.

In addition, the transistor 102 has its gate terminal connected to a gate voltage terminal 107.

A control signal that carries out ON/OFF control of the transistor 101 is input through the gate voltage terminal 104, and a control signal that carries out ON/OFF control of the transistor 102 is input through the gate voltage terminal 107.

If a high-frequency signal is input through the input terminal 103 of the cascode amplifier while the transistors 101 and 102 are in the ON state, the high-frequency signal amplified by the transistors 101 and 102 is output from the output terminal 106 of the cascode amplifier.

As for the cascode amplifier, since the withstand voltage between the terminals of the transistor 102 is made higher than the withstand voltage between the terminals of the transistor 101, it can maintain the high output power which is considered essential for mobile communication terminals.

### PRIOR ART DOCUMENT

### Patent Document

Patent Document 1: Japanese Patent Laid-Open No. 2001-217661 (Paragraph [0011]).

### DISCLOSURE OF THE INVENTION

### Problems to be Solved by the Invention

With the foregoing configuration, the conventional cascode amplifier can maintain high output power. When the gain is insufficient, however, it is usually necessary to connect the cascode amplifiers in series, which offers a problem of increasing the circuit size.

In addition, although increasing the current flowing through the transistors enables increasing the gain without changing the circuit size, this offers a problem of reducing the efficiency.

The present invention is implemented to solve the foregoing problems. Therefore it is an object of the present invention to provide an amplifier circuit capable of downsizing and increasing the gain.

### Means for Solving the Problem

An amplifier in accordance with the present invention comprises N (N is a natural number not less than two) stages of cascode amplifiers connected in series, wherein the cascode amplifier includes a first transistor and a second transistor connected in cascode, the first transistor having its source terminal or emitter terminal grounded, and the second transistor having its source terminal or emitter terminal connected to the drain terminal or collector terminal of the first transistor, and wherein in at least one of the cascode amplifiers, the gate width or emitter area of the first transistor is made smaller than the gate width or emitter area of the second transistor; and the gate width or emitter area of the first transistor at least at a Pth stage (P is a natural number of 2≦P≦N) is equal to the gate width or emitter area of the second transistor at a (P-1)th stage.

### Advantages of the Invention

According to the present invention, since the gate width or emitter area of the first transistor is made smaller than the gate width or emitter area of the second transistor in at least one of the cascode amplifiers, and the gate width or emitter area of the first transistor at least at the Pth stage (P is a natural number of 2≦P≦N) is equal to the gate width or emitter area of the second transistor at the (P-1)th stage, it has an advantage of being able to downsize and to increase gain.

### BRIEF DESCRIPTION OF THE DRAWINGS

FIG. 1 is a diagram showing a configuration of a cascode amplifier of an embodiment 1 in accordance with the present invention;

FIG. 2 is a diagram illustrating gain difference between the cascode amplifier of FIG. 1 of the embodiment 1 and the cascode amplifier of FIG. 9 of the conventional example;

FIG. 3 is a diagram showing a configuration of an amplifier circuit of an embodiment 2 in accordance with the present invention;

FIG. 4 is a diagram showing a configuration of an amplifier circuit of an embodiment 3 in accordance with the present invention;

FIG. 5 is a diagram showing a configuration of an amplifier circuit of an embodiment 4 in accordance with the present invention;

FIG. 6 is a diagram showing a configuration of an amplifier circuit of the embodiment 4 in accordance with the present invention;

FIG. 7 is a diagram showing a configuration of an amplifier circuit of an embodiment 5 in accordance with the present invention;

FIG. 8 is a diagram showing a configuration of an amplifier circuit of an embodiment 6 in accordance with the present invention;

FIG. 9 is a diagram showing a configuration of an amplifier circuit of an embodiment 7 in accordance with the present invention;

FIG. 10 is a diagram showing a configuration of an amplifier circuit of an embodiment 8 in accordance with the present invention;

FIG. 11 is a diagram showing a configuration of a common cascode amplifier; and

FIG. 12 is a diagram showing a configuration of a cascode amplifier disclosed in the Patent Document 1.

### BEST MODE FOR CARRYING OUT THE INVENTION

The best mode for carrying out the invention will now be described with reference to the accompanying drawings.

### Embodiment 1

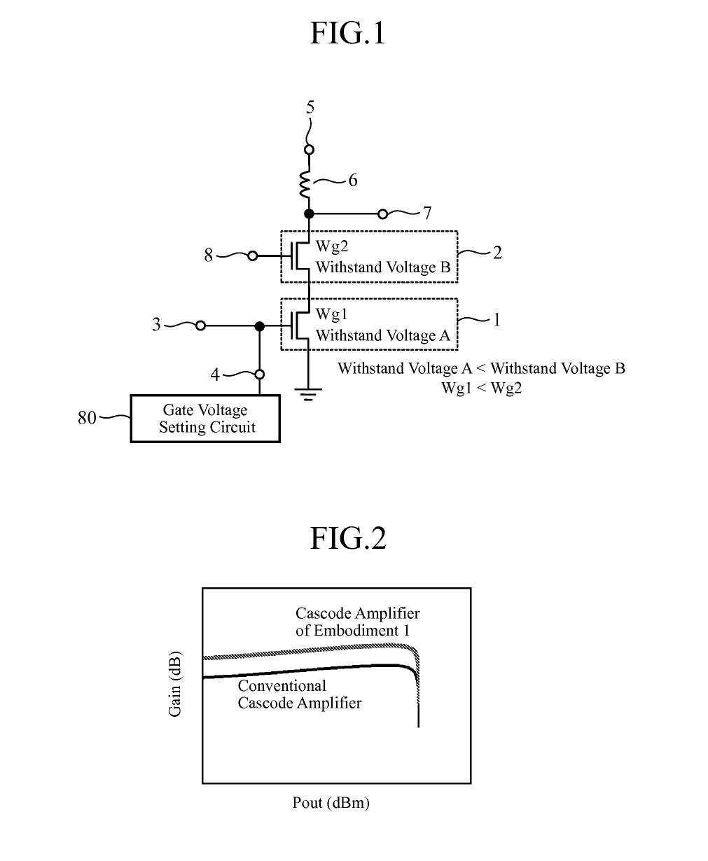

FIG. 1 is a diagram showing a configuration of cascode amplifier of an embodiment 1 in accordance with the present invention.

In FIG. 1, a FET 1 which is a first transistor has its source terminal grounded, and its gate terminal connected to an input terminal 3 of the cascode amplifier and to a gate voltage terminal 4.

The withstand voltage between the terminals of the FET 1 is withstand voltage A and the gate width of the FET 1 is Wg1.

The input terminal 3 is a terminal for inputting a high-frequency signal, and the gate voltage terminal 4 is a terminal for inputting a control signal for controlling ON/OFF of the FET 1.

A FET 2 which is a second transistor has its source terminal connected to the drain terminal of the FET 1, and its drain terminal connected to a supply voltage terminal 5 via a DC feed inductor 6, and to an output terminal 7 of the cascode amplifier. In addition, it has its gate terminal connected to a gate voltage terminal 8.

The withstand voltage between the terminals of the FET 2 is withstand voltage B which is higher than the withstand voltage between the terminals of the FET 1 (withstand voltage A), and the gate width of the FET 2 is Wg2 which is wider than the gate width of the FET 1 (Wg1).

withstand voltage A<withstand voltage B

Wg1<Wg2

The supply voltage terminal 5 is a terminal for inputting the supply voltage, the output terminal 7 is a terminal for outputting the high-frequency signal amplified by the FETs 1 and 2, and the gate voltage terminal 8 is a terminal for inputting the control signal for controlling ON/OFF of the FET 2.

A gate voltage setting circuit 80, which is connected to the gate voltage terminal 4, is a voltage setting circuit for setting the gate voltage of the FET 1.

Next, the operation will be described.

The gate voltage set by the gate voltage setting circuit 80, which is the control signal that controls ON/OFF of the FET 1, is supplied from the gate voltage setting circuit 80 to the gate voltage terminal 4. Thus, the control signal that controls ON/OFF of the FET 1 is input via the gate voltage terminal 4.

On the other hand, the control signal that controls ON/OFF of the FET 2 is input via the gate voltage terminal 8.

When the high-frequency signal is input via the input terminal 3 of the cascode amplifier while the FETs 1 and 2 are in the ON state, the high-frequency signal is amplified by the FETs 1 and 2, and the high-frequency signal after the amplification is output from the output terminal 7 of the cascode amplifier.

In the cascode amplifier, since the withstand voltage between the terminals of the FET 2 (withstand voltage B) is higher than the withstand voltage between the terminals of the FET 1 (withstand voltage A), it can maintain the high output power which is considered essential for the mobile communication terminal.

The present embodiment 1 differs from the conventional cascode amplifier in that the gate width of the FET 1 (Wg1) is smaller than the gate width of the FET 2 (Wg2).

Thus, if it is assumed that the current flowing through the cascode amplifier is Ic1 when the gate width of the FET 1 (Wg1) is narrower than the gate width of the FET 2 (Wg2), and that the current flowing through the cascode amplifier is Ic2 if the gate width of the FET 1 (Wg1) equals the gate width of the FET 2 (Wg2), the gate voltage setting circuit 80 sets the gate voltage of the FET 1 in such a manner as to satisfy the relationship of the following Expression (1).

Ic1=Ic2*(Wg2/Wg1) (1)

In this way, increasing the gate voltage input via the gate voltage terminal 4 of the FET 1 by the amount of reduction in the gate width of the FET 1 (Wg1) from the gate width of the FET 2 (Wg2) can increase the idle current, thereby being able to increase the current density of the FET 1 and to improve the gain.

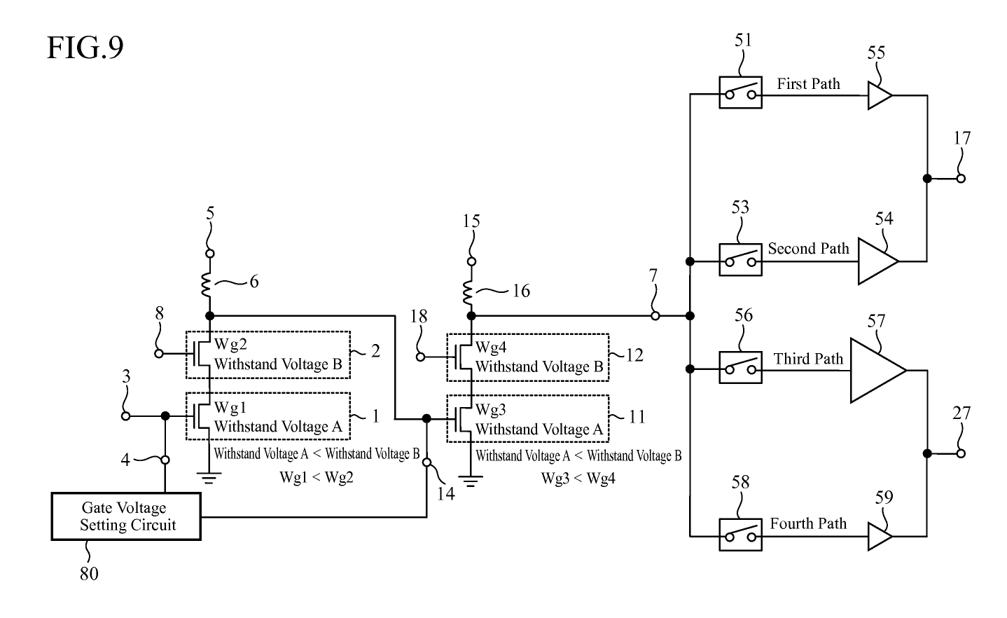

FIG. 2 is a diagram illustrating the gain difference between the cascode amplifier of FIG. 1 of the embodiment 1 and the cascode amplifier of FIG. 9 of the conventional example.

As is clear from FIG. 2, the cascode amplifier of FIG. 1 has the gain higher than the cascode amplifier of FIG. 9 if the output power is the same.

Incidentally, as a concrete example of the gate widths of the FETs 1 and 2, it is conceivable to make the gate width of the FET 1 (Wg1) half or less of the gate width of the FET 2 (Wg2).

In addition, as for the cascode amplifier, it is conceivable to construct it with a monolithic microwave integrated circuit, for example.

As is clear from the above, according to the present embodiment 1, it is configured in such a manner that the withstand voltage between the terminals of the FET 2 (withstand voltage B) is higher than the withstand voltage between the terminals of the FET 1 (withstand voltage A) and that the gate width of the FET 1 (Wg1) is narrower than the gate width of the FET 2 (Wg2). Accordingly, it offers an advantage of being able to increase the gain while maintaining the high output power.

In addition, since the gate width of the FET 1 (Wg1) connected to the input terminal 3 is narrower, it offers an advantage of being able to downsize the cascode amplifier.

Although the present embodiment 1 shows the cascode amplifier having the FET 1 and FET 2 connected in cascode, transistors connected in cascode are not limited to FETs, but can be bipolar transistors connected in cascode, for example.

In this case, a cascode amplifier similar to that of FIG. 1 can be realized by handling the source terminals of the transistors as emitter terminals, drain terminals as collector terminals, and gate terminals as base terminals, and by replacing the gate widths of the FETs by the emitter areas of the transistors.

More specifically, making the emitter area of the bipolar transistor substituted for the FET 1 smaller than the emitter area of the bipolar transistor substituted for the FET 2 makes it possible to increase the gain and to downsize the cascode amplifier.

In addition, although the present embodiment 1 shows the cascode amplifier having two FETs connected in cascode, a cascode amplifier having M (M is a natural number greater than two) FETs connected in cascode can be possible.

When M FETs are connected in cascode, assuming that the FET connected to the input terminal 3 is the first FET and the FET connected to the output terminal 7 is Mth FET, an mth FET (m=2, 3, . . . , M) has its source terminal connected to the drain terminal of (m-1)th FET, and the gate width of the (m-1)th FET is made narrower than the gate width of the mth FET.

### Embodiment 2

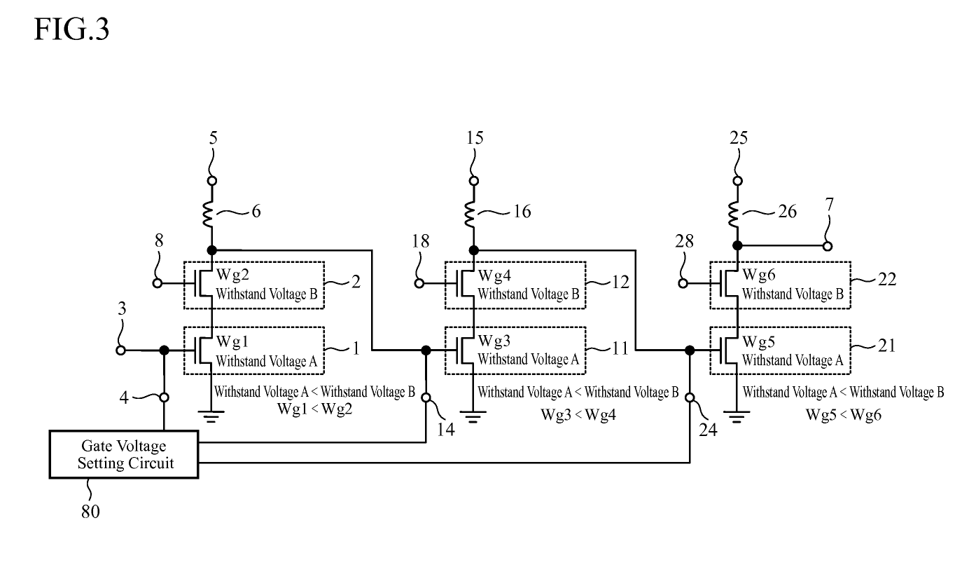

FIG. 3 is a diagram showing a configuration of an amplifier circuit of an embodiment 2 in accordance with the present invention. In FIG. 3, since the same reference numerals as those of FIG. 1 designate the same or like components, their description will be omitted.

FIG. 3 shows an amplifier circuit having three cascode amplifiers connected in series. The number of stages of the cascode amplifiers, however, is not limited to a specific value, but can be any desired number of stages.

A FET 11, which is a first transistor, has its source terminal grounded, and its gate terminal connected to the drain terminal of the FET 2 and to a gate voltage terminal 14.

The withstand voltage between the terminals of the FET 11 is withstand voltage A, and the gate width of the FET 11 is Wg3.

The gate voltage terminal 14 is a terminal for inputting a control signal for controlling ON/OFF of the FET 11. As the control signal for controlling ON/OFF of the FET 11, the gate voltage set by the gate voltage setting circuit 80 is supplied.

A FET 12, which is a second transistor, has its source terminal connected to the drain terminal of the FET 11, and its drain terminal connected to a supply voltage terminal 15 via a DC feed inductor 16. In addition, its gate terminal is connected to a gate voltage terminal 18.

The withstand voltage between the terminals of the FET 12 is withstand voltage B which is higher than the withstand voltage between the terminals of the FET 11 (withstand voltage A), and the gate width of the FET 12 is Wg4 which is wider than the gate width of the FET 11 (Wg3).

withstand voltage A<withstand voltage B

Wg3<Wg4

The supply voltage terminal 15 is a terminal for feeding the supply voltage, and the gate voltage terminal 18 is a terminal for inputting the control signal for controlling ON/OFF of the FET 12.

A FET 21, which is a first transistor, has its source terminal grounded, and its gate terminal connected to the drain terminal of the FET 12 and to a gate voltage terminal 24.

The withstand voltage between the terminals of the FET 21 is withstand voltage A, and the gate width of the FET 21 is Wg5.

The gate voltage terminal 24 is a terminal for inputting a control signal for controlling ON/OFF of the FET 21. As the control signal for controlling ON/OFF of the FET 21, the gate voltage set by the gate voltage setting circuit 80 is supplied.

A FET 22, which is a second transistor, has its source terminal connected to the drain terminal of the FET 21, and its drain terminal connected to a supply voltage terminal 25 via a DC feed inductor 26 and to the output terminal 7. In addition, its gate terminal is connected to a gate voltage terminal 28.

The withstand voltage between the terminals of the FET 22 is withstand voltage B which is higher than the withstand voltage between the terminals of the FET 21 (withstand voltage A), and the gate width of the FET 22 is Wg6 which is wider than the gate width of the FET 21 (Wg4).

withstand voltage A<withstand voltage B

Wg5<Wg6

The supply voltage terminal 25 is a terminal for feeding the supply voltage, and the gate voltage terminal 28 is a terminal for inputting the control signal for controlling ON/OFF of the FET 22.

Next, the operation will be described.

The gate voltages set by the gate voltage setting circuit 80 are the control signals for controlling ON/OFF of the FETs 1, 11 and 21. Thus, by supplying the gate voltages from the gate voltage setting circuit 80 to the gate voltage terminals 4, 14 and 24, the control signals for controlling ON/OFF of the FETs 1, 11 and 21 are input to the gate voltage terminals 4, 14 and 24.

Likewise, the control signals for controlling ON/OFF of the FETs 2, 12 and 22 are input through the gate voltage terminals 8, 18 and 28.

If a high-frequency signal is input through the input terminal 3 while the FETs 1, 11, 21, 2, 12 and 22 are in the ON state, the high-frequency signal is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the gate terminal of the FET 21.

When the high-frequency signal amplified by the FETs 11 and 12 is supplied to the gate terminal of the FET 21, the high-frequency signal is amplified by the FETs 21 and 22, and the high-frequency signal after the amplification is output from the output terminal 7.

In the present embodiment 2, since the withstand voltage between the terminals of the FETs 2, 12 and 22 (withstand voltage B) is higher than the withstand voltage between the terminals of the FETs 1, 11 and 21 (withstand voltage A), it can maintain the high output power which is considered essential for mobile communication terminals. In addition, since a plurality of cascode amplifiers are connected in series, it can further increase the output power of the high-frequency signal.

In addition, in the present embodiment 2, since the gate widths of the FETs 1, 11 and 21 (Wg1, Wg3 and Wg5) are made narrower than the gate widths of the FETs 2, 12 and 22 (Wg2, Wg4 and Wg6), increasing the idle current by increasing the gate voltages of the FETs 1, 11 and 21 can increase the current density of the FETs 1, 11 and 21, thereby being able to increase the gain and to downsize the cascode amplifiers.

Incidentally, as for the gate voltages supplied from the gate voltage setting circuit 80 to the FETs 1, 11 and 21, they may be equal or different.

Although the present embodiment 2 shows the cascode amplifiers each having two FETs connected in cascode, the transistors connected in cascode are not limited to FETs, but can be bipolar transistors connected in cascode, for example.

In this case, replacing the gate widths of the FETs by the emitter areas of the transistors enables achieving the same advantages as the amplifier circuit of FIG. 3.

More specifically, by making the emitter areas of the bipolar transistors substituted for the FETs 1, 11 and 21 smaller than the emitter areas of the bipolar transistors substituted for the FETs 2, 12 and 22, it becomes possible not only to increase the gain, but also to downsize the cascode amplifiers.

The present embodiment 2 shows an example of the amplifier circuit with three-stage cascode amplifiers connected in series, and in each cascode amplifier, the gate width of the input side FET is narrower than the gate width of the output side FET. However, a configuration comprising at least one or more stages of the cascode amplifiers having the foregoing construction can increase the gain as compared with an amplifier circuit having cascode amplifiers of FIG. 12 connected in series, and can increase the gain and downsize the cascode amplifiers.

Here, as for the relationships between the gate widths (Wg1, Wg3 and Wg5) of the FETs 1, 11 and 21, if Wg1<Wg3<Wg5, the closer the FET is to the output terminal 7, the higher power it can output.

In addition, as for the gate widths (Wg2, Wg4 and Wg6) of the FETs 2, 12 and 22, if Wg2<Wg4<Wg6, the closer the FET is to the output terminal 7, the higher power it can output.

Incidentally, it is conceivable that the cascode amplifiers are constructed by a monolithic microwave integrated circuit, for example.

### Embodiment 3

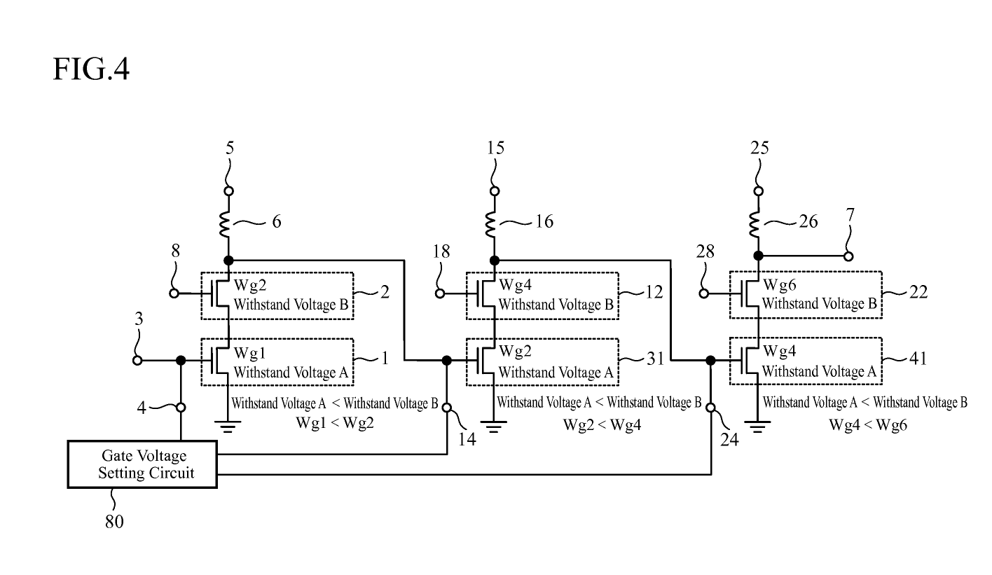

FIG. 4 is a diagram showing a configuration of an amplifier circuit of an embodiment 3 in accordance with the present invention. In FIG. 4, since the same reference numerals as those of FIG. 3 designate the same or like components, their description will be omitted.

FIG. 4 shows an amplifier circuit having three cascode amplifiers connected in series. The number of stages of the cascode amplifiers, however, is not limited to a specific number, but can be any desired number of stages.

A FET 31, which is a first transistor, has its source terminal grounded, and its gate terminal connected to the drain terminal of the FET 2 and to the gate voltage terminal 14.

The withstand voltage between the terminals of the FET 31 is the withstand voltage A, and the gate width of the FET 31 is Wg2 which is the same as that of the FET 2.

A FET 41, which is a first transistor, has its source terminal grounded, and its gate terminal connected to the drain terminal of the FET 12 and to the gate voltage terminal 24.

The withstand voltage between the terminals of the FET 41 is the withstand voltage A, and the gate width of the FET 41 is Wg4 which is the same as that of the FET 12.

Although FIG. 4 shows an example of the amplifier circuit comprising three-stage cascode amplifiers connected in series, when the number of stages of the cascode amplifiers is N (N is a natural number not less than two), the present embodiment 3 has such a configuration in which the gate width of the input side FET at a Pth stage (P is a natural number not less than two and P≦N) is equal to the gate width of the output side FET at the (P-1)th stage.

Next, the operation will be described.

The gate voltages set by the gate voltage setting circuit 80 are the control signals for controlling ON/OFF of the FETs 1, 31 and 41. Thus, by supplying the gate voltages from the gate voltage setting circuit 80 to the gate voltage terminals 4, 14 and 24, the control signals for controlling ON/OFF of the FETs 1, 31 and 41 are input through the gate voltage terminals 4, 14 and 24.

On the other hand, the control signals for controlling

ON/OFF of the FETs 2, 12 and 22 are input through the gate voltage terminals 8, 18 and 28.

If the high-frequency signal is input through the input terminal 3 while the FETs 1, 31, 41, 2, 12 and 22 are in the ON state, the high-frequency signal is amplified by the FETs 1 and 2, and the high-frequency signal after the amplification is supplied to the gate terminal of the FET 31.

When the high-frequency signal amplified by the FETs 1 and 2 is supplied to the gate terminal of the FET 31, the high-frequency signal is amplified by the FETs 31 and 12, and the high-frequency signal after the amplification is supplied to the gate terminal of the FET 41.

When the high-frequency signal amplified by the FETs 31 and 12 is supplied to the gate terminal of the FET 41, the high-frequency signal is amplified by the FETs 41 and 22, and the high-frequency signal after the amplification is output from the output terminal 7.

In the present embodiment 3, since the withstand voltage between the terminals of the FETs 2, 12 and 22 (withstand voltage B) is higher than the withstand voltage between the terminals of the FETs 1, 31 and 41 (withstand voltage A), it can maintain high output power which is considered essential for mobile communication terminals. In addition, since a plurality of cascode amplifiers are connected in series, it can further increase the output power of the high-frequency signal.

In addition, in the present embodiment 3, since the gate widths (Wg1, Wg2 and Wg4) of the FETs 1, 31 and 41 are made narrower than the gate widths (Wg2, Wg4 and Wg6) of the FETs 2, 12 and 22, increasing the idle current by increasing the gate voltages of the FETs 1, 31 and 41 can increase the current density of the FETs 1, 31 and 41, thereby being able to increase the gain and to downsize the cascode amplifiers.

Incidentally, as for the gate voltages supplied from the gate voltage setting circuit 80 to the FETs 1, 31 and 41, they may be equal or different.

Furthermore, in the present embodiment 3, since the gate width Wg2 of the FET 31 is equal to the gate width Wg2 of the FET 2, and the gate width Wg4 of the FET 41 is equal to the gate width Wg4 of the FET 12, the impedance transformation ratio of the FETs between the cascode amplifiers in front and behind becomes small, which can facilitate the conjugate matching. Accordingly, it can increase the gain more than the foregoing embodiment 2.

Although the present embodiment 3 shows the cascode amplifiers each having two FETs connected in cascode, transistors connected in cascode are not limited to FETs, but can be bipolar transistors connected in cascode, for example.

In this case, replacing the gate widths of the FETs by the emitter areas of the transistors enables achieving the same advantages as the amplifier circuit of FIG. 4 as described above.

More specifically, by making the emitter areas of the bipolar transistors substituted for the FETs 1, 31 and 41 smaller than the emitter areas of the bipolar transistors substituted for the FETs 2, 12 and 22, it becomes possible not only to increase the gain, but also to downsize the cascode amplifier.

In addition, by making the emitter area of the bipolar transistor substituted for the FET 31 equal to the emitter area of the bipolar transistor substituted for the FET 2, and by making the emitter area of the bipolar transistor substituted for the FET 41 equal to the emitter area of the bipolar transistor substituted for the FET 12, the present embodiment 3 can further increase its gain.

Here, as for the relationships between the gate widths (Wg1, Wg2 and Wg4) of the FETs 1, 31 and 41, if Wg1<Wg2<Wg4, the closer the FET is to the output terminal 7, the higher power it can output.

In addition, as for the gate widths (Wg2, Wg4 and Wg6) of the FETs 2, 12 and 22, if Wg2<Wg4<Wg6, the closer the FET is to the output terminal 7, the higher power it can output.

Incidentally, it is conceivable that the cascode amplifies are constructed by a monolithic microwave integrated circuit, for example.

### Embodiment 4

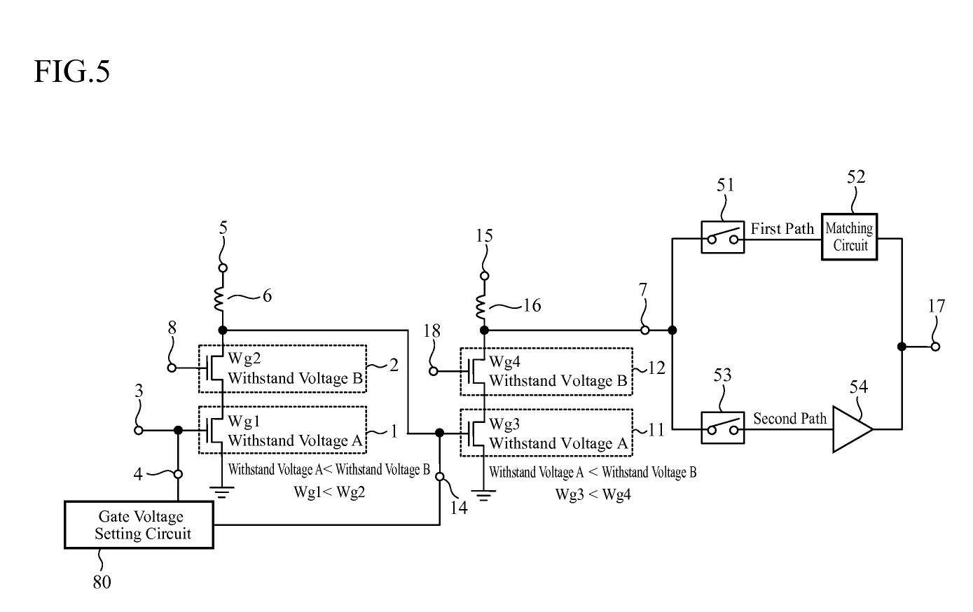

FIG. 5 is a diagram showing a configuration of an amplifier circuit of an embodiment 4 in accordance with the present invention. In FIG. 5, since the same reference numerals as those of FIG. 3 designate the same or like components, their description will be omitted.

FIG. 5 shows an amplifier circuit having two cascode amplifiers connected in series. The number of stages of the cascode amplifiers, however, is not limited to a specific number, but can be any desired number of stages.

The FET 12 has its drain terminal connected to a first path (bypass path) and a second path, and the first path and second path are connected to the output terminal 7.

The first path is comprised of a series circuit of a bypass switch 51 and a matching circuit 52. In a first operation mode in which the requested output power is low, the bypass switch 51 is controlled to the ON state, whereas in a second operation mode in which the requested output power is high, the bypass switch 51 is controlled to the OFF state.

Incidentally, the ON/OFF state of the bypass switch 51 is controlled by a control circuit not shown.

The second path is comprised of a series circuit of a signal path switch 53 and a final stage amplifier 54. In the first operation mode in which the requested output power is low, the signal path switch 53 is controlled to the OFF state, whereas in the second operation mode in which the requested output power is high, the signal path switch 53 is controlled to the ON state.

Incidentally, the ON/OFF state of the signal path switch 53 is controlled by a control circuit not shown

Next, the operation will be described.

The gate voltages set by the gate voltage setting circuit 80 are the control signals for controlling ON/OFF of the FETs 1 and 11. Thus, by supplying the gate voltages from the gate voltage setting circuit 80 to the gate voltage terminals 4 and 14, the control signals for controlling ON/OFF of the FETs 1 and 11 are input through the gate voltage terminals 4 and 14.

On the other hand, the control signals for controlling ON/OFF of the FETs 2 and 12 are input through the gate voltage terminals 8 and 18.

In the first operation mode in which the requested output power is low, the bypass switch 51 is controlled to the ON state and the signal path switch 53 is controlled to the OFF state by the control circuit not shown. In addition, the supply voltage to the final stage amplifier 54 is stopped.

Accordingly, if it enters into the first operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the matching circuit 52 of the first path.

After that, the high-frequency signal after the amplification passing through the matching by the matching circuit 52 is output from the output terminal 17 of the amplifier circuit.

In the second operation mode in which the requested output power is high, the bypass switch 51 is controlled to the OFF state and the signal path switch 53 is controlled to the ON state by the control circuit not shown. In addition, the final stage amplifier 54 is fed with the supply voltage.

Accordingly, if it enters into the second operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the final stage amplifier 54 of the second path.

When the high-frequency signal amplified by the FETs 11 and 12 is supplied to the final stage amplifier 54, the high-frequency signal is amplified by the final stage amplifier 54, and the high-frequency signal after the amplification is output from the output terminal 17 of the amplifier circuit.

The present embodiment 4 is configured in such a manner as to comprise the first path and the second path across the drain terminal of the FET 12 and the output terminal 17, and to switch the path through which the high-frequency signal passes in accordance with the requested output power. Accordingly, besides the same advantages of the foregoing embodiments 2 and 3, it offers an advantage of being able to switch the output power of the high-frequency signal appropriately.

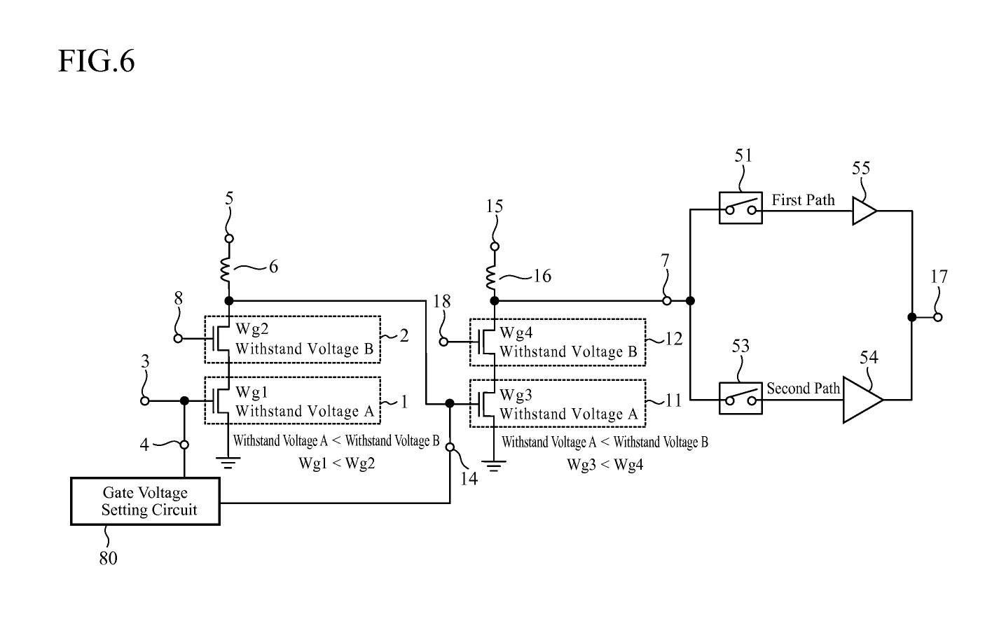

Here, although the example is shown in which the first path is comprised of the series circuit of the bypass switch 51 and the matching circuit 52, a configuration as shown in FIG. 6 is also possible in which the first path is comprised of a series circuit of the bypass switch 51 and a bypass amplifier 55. As the bypass amplifier 55, a cascode amplifier can be used, for example.

In addition, as for the gate voltages supplied from the gate voltage setting circuit 80 to the FETs 1 and 11, they are equal or different, or they can be altered in conformity with the operation mode.

Although the present embodiment 4 shows the cascode amplifier having two FETs connected in cascode, the transistors connected in cascode are not limited to FETs, but can be bipolar transistors connected in cascode, for example.

In this case, replacing the gate widths of the FETs by the emitter areas of the transistors enables achieving the same advantages as the amplifier circuits of FIG. 5 and FIG. 6.

### Embodiment 5

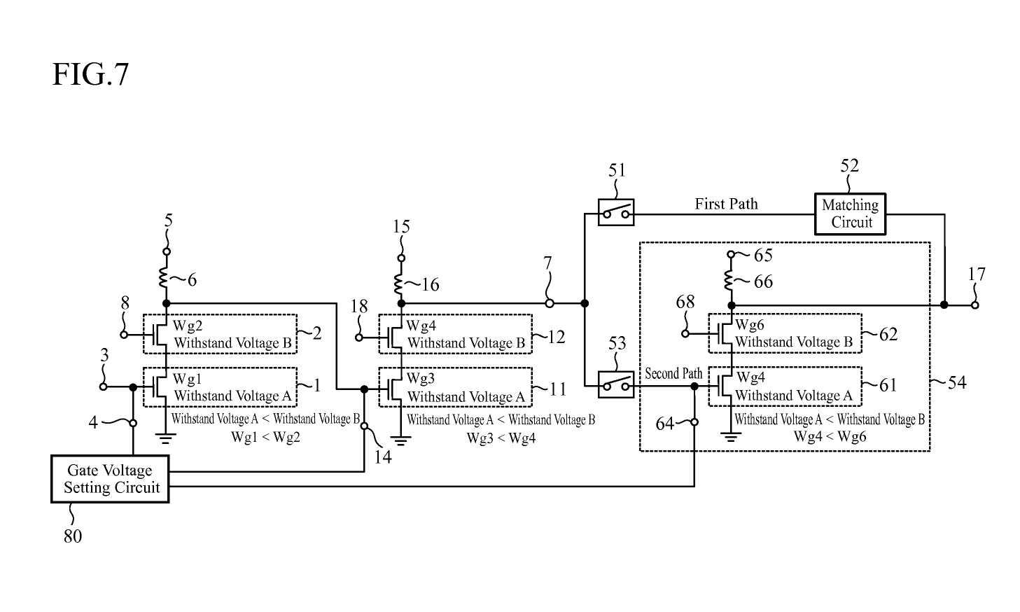

FIG. 7 is a diagram showing a configuration of an amplifier circuit of an embodiment 5 in accordance with the present invention. In FIG. 7, since the same reference numerals as those of FIG. 5 designate the same or like components, their description will be omitted.

FIG. 7 shows an amplifier circuit having two cascode amplifiers connected in series. The number of stages of the cascode amplifiers, however, is not limited to a specific number, but can be any desired number of stages.

In FIG. 7, the final stage amplifier 54 is comprised of a cascode amplifier.

A FET 61 has its source terminal grounded, and its gate terminal connected to the signal path switch 53 and to a gate voltage terminal 64.

The withstand voltage between the terminals of the FET 61 is withstand voltage A, and the gate width of the FET 61 is Wg4 which is the same as that of the FET 12.

The gate voltage terminal 64 is a terminal for inputting the control signal that carries out ON/OFF control of the FET 61.

A FET 62 has its source terminal connected to the drain terminal of the FET 61, and its drain terminal connected to a supply voltage terminal 65 via a DC feed inductor 66 and to the output terminal 17. In addition, its gate terminal is connected to a gate voltage terminal 68.

The withstand voltage between the terminals of the FET 62 is the withstand voltage B which is higher than the withstand voltage between the terminals of the FET 61 (withstand voltage A), and the gate width of the FET 62 is Wg6 which is wider than the gate width (Wg4) of the FET 61.

withstand voltage A<withstand voltage B

Wg4<Wg6

The supply voltage terminal 65 is a terminal for inputting the supply voltage, and the gate voltage terminal 68 is a terminal for inputting the control signal that controls ON/OFF of the FET 62.

Next, the operation will be described.

The gate voltages set by the gate voltage setting circuit 80 are the control signals for controlling ON/OFF of the FETs 1 and 11. Thus, by supplying the gate voltages from the gate voltage setting circuit 80 to the gate voltage terminals 4 and 14, the control signals for controlling ON/OFF of the FETs 1 and 11 are input through the gate voltage terminals 4 and 14.

On the other hand, the control signals for controlling ON/OFF of the FETs 2 and 12 are input through the gate voltage terminals 8 and 18.

In addition, the other gate voltage set by the gate voltage setting circuit 80 is the control signal for controlling ON/OFF of the FET 61 of the final stage amplifier 54. Thus, by supplying the gate voltage from the gate voltage setting circuit 80 to the gate voltage terminal 64, the control signal for controlling ON/OFF of the FET 61 of the final stage amplifier 54 is input through the gate voltage terminal 64.

On the other hand, the control signal for controlling ON/OFF of the FET 62 of the final stage amplifier 54 is input through the gate voltage terminal 68.

In the first operation mode in which the requested output power is low, the bypass switch 51 is controlled to the ON state and the signal path switch 53 is controlled to the OFF state by the control circuit not shown. In addition, the supply voltage to the supply voltage terminal 65 of the final stage amplifier 54 is stopped.

Accordingly, if it enters into the first operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the matching circuit 52 of the first path.

After that, the high-frequency signal after the amplification passing through the matching by the matching circuit 52 is output from the output terminal 17 of the amplifier circuit.

In the second operation mode in which the requested output power is high, the bypass switch 51 is controlled to the OFF state and the signal path switch 53 is controlled to the ON state by the control circuit not shown. In addition, the supply voltage is fed to the supply voltage terminal 65 of the final stage amplifier 54.

Accordingly, if it enters into the second operation mode when the FETs 1, 11, 2, 12, 61 and 62 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the final stage amplifier 54 of the second path.

When the high-frequency signal amplified by the FETs 11 and 12 is supplied to the final stage amplifier 54, the high-frequency signal is amplified by the FETs 61 and 62, and the high-frequency signal after the amplification is output from the output terminal 17 of the amplifier circuit.

Since the present embodiment 5 has the same basic configuration as the foregoing embodiment 4, it can offer the same advantages. In addition, since the final stage amplifier 54 of FIG. 7 is comprised of the cascode amplifier, and the withstand voltage between the terminals of the FET 62 (withstand voltage B) is higher than the withstand voltage between the terminals of the FET 61 (withstand voltage A), it can maintain the high output power which is considered essential for mobile communication terminals.

In addition, since the gate width (Wg4) of the FET 61 is made narrower than the gate width (Wg6) of the FET 62, increasing the gate voltage of the FET 61 to increase the idle current makes it possible to increase the current density of the FET 61 and to increase the gain, and to downsize the cascode amplifier.

Furthermore, since the gate width Wg4 of the FET 61 of the final stage amplifier 54 is equal to the gate width Wg4 of the FET 12, the impedance transformation ratio between the FET 61 of the final stage amplifier 54 and the FET 12 becomes small, which can facilitate the conjugate matching.

Although the present embodiment 5 shows the cascode amplifiers each having two FETs connected in cascode, transistors connected in cascode are not limited to FETs, but can be bipolar transistors connected in cascode, for example.

In this case, replacing the gate widths of the FETs by the emitter areas of the transistors enables achieving the same advantages as the amplifier circuits of FIG. 5 and FIG. 6.

### Embodiment 6

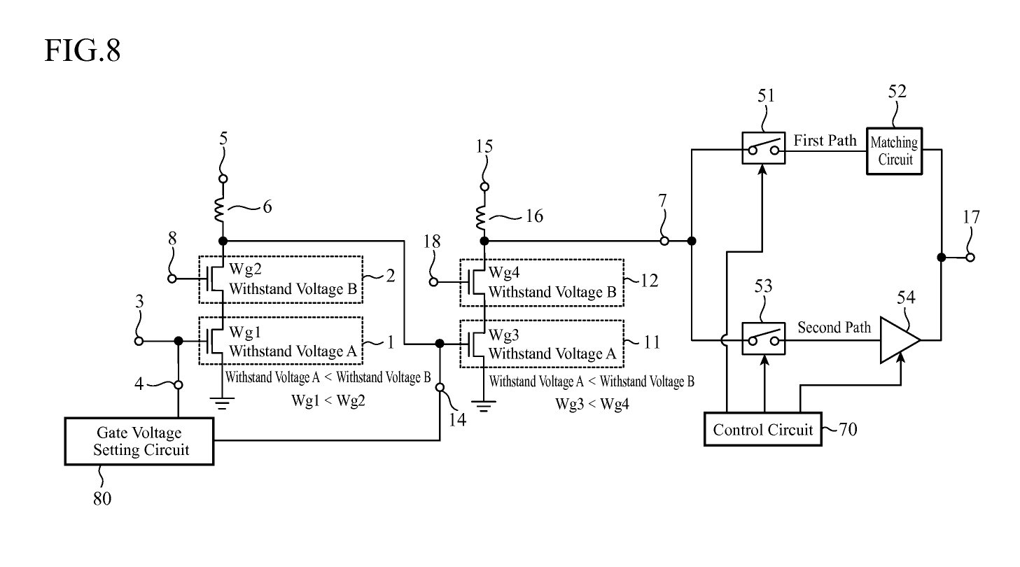

FIG. 8 is a diagram showing a configuration of an amplifier circuit of an embodiment 6 in accordance with the present invention. In FIG. 8, since the same reference numerals as those of FIG. 5 and FIG. 7 designate the same or like components, their description will be omitted.

FIG. 8 shows an amplifier circuit having two cascode amplifiers connected in series. The number of stages of the cascode amplifiers, however, is not limited to a specific number, but can be any desired number of stages.

A control circuit 70 is a circuit that controls, in the first operation mode in which the requested output power is low, the bypass switch 51 to the ON state and the signal path switch 53 to the OFF state, and controls, in the second operation mode in which the requested output power is high, the bypass switch 51 to the OFF state and the signal path switch 53 to the ON state.

In addition, the control circuit 70 stops feeding the supply voltage to the final stage amplifier 54 in the first operation mode, but supplies the voltage to the final stage amplifier 54 in the second operation mode.

Although the foregoing embodiments 4 and 5 show the examples in which the bypass switch 51, signal path switch 53 and final stage amplifier 54 are controlled by the control circuit not shown, a configuration is also possible in which the control circuit 70 controls the bypass switch 51, signal path switch 53 and final stage amplifier 54 as shown in FIG. 8.

More specifically, the control circuit 70 controls, in the first operation mode in which the requested output power is low, the bypass switch 51 to the ON state and the signal path switch 53 to the OFF state, and stops feeding the supply voltage to the final stage amplifier 54.

This enables the high-frequency signal amplified by the FETs 11 and 12 to pass through the matching circuit 52 of the first path and to be output from the output terminal 17 of the amplifier circuit.

On the other hand, in the second operation mode in which the requested output power is high, it controls the bypass switch 51 to the OFF state and the signal path switch 53 to the ON state, and supplies the voltage to the final stage amplifier 54.

This enables the high-frequency signal amplified by the FETs 11 and 12 to be amplified by the final stage amplifier 54 of the second path, and the high-frequency signal after the amplification to be output from the output terminal 17 of the amplifier circuit.

The present embodiment 6 can also offer the same advantages as those of the foregoing embodiments 4 and 5.

Although the example is shown here in which the first path is comprised of the series circuit of the bypass switch 51 and the matching circuit 52, the first path can also be comprised of the series circuit of the bypass switch 51 and bypass amplifier 55 as shown in FIG. 6 of the foregoing embodiment 5.

In this case, the control circuit 70 controls, in the first operation mode in which the requested output power is low, the bypass switch 51 to the ON state and the signal path switch 53 to the OFF state, and supplies the bypass amplifier 55 with the voltage and stops feeding the supply voltage to the final stage amplifier 54.

On the other hand, it controls, in the second operation mode in which the requested output power is high, the bypass switch 51 to the OFF state and the signal path switch 53 to the ON state, and stops feeding the voltage to the bypass amplifier 55 and supplies the voltage to the final stage amplifier 54.

Although the present embodiment 6 shows the cascode amplifier having two FETs connected in cascode, transistors connected in cascode are not limited to FETs, but can be bipolar transistors connected in cascode, for example.

In this case, replacing the gate widths of the FETs by the emitter areas of the transistors enables achieving the same advantages as the amplifier circuit of FIG. 7. In addition, the final stage amplifier 54 can be comprised of the cascode amplifier as shown in FIG. 7.

### Embodiment 7

FIG. 9 is a diagram showing a configuration of an amplifier circuit of an embodiment 7 in accordance with the present invention. In FIG. 9, since the same reference numerals as those of FIG. 5 and FIG. 6 designate the same or like components, their description will be omitted.

FIG. 9 shows an amplifier circuit having two cascode amplifiers connected in series. The number of stages of the cascode amplifiers, however, is not limited to a specific number, but can be any desired number of stages.

FIG. 9 shows a configuration that has four signal transmission paths from first to fourth paths, and the individual signal transmission paths have amplifiers (final stage amplifiers 54 and 57 and bypass amplifiers 55 and 59) with different saturation powers. For this reason, the present embodiment 7 can have the first operation mode and the second operation mode for two modulation schemes.

Next, the operation will be described.

The gate voltages set by the gate voltage setting circuit 80 are the control signals for controlling ON/OFF of the FETs 1 and 11. Thus, by supplying the gate voltages from the gate voltage setting circuit 80 to the gate voltage terminals 4 and 14, the control signals for controlling ON/OFF of the FETs 1 and 11 are input through the gate voltage terminals 4 and 14.

On the other hand, the control signals for controlling ON/OFF of the FETs 2 and 12 are input through the gate voltage terminals 8 and 18.

First, a case will be described in which the modulating wave signal A is input through the input terminal 3 of the cascode amplifier.

In the first operation mode in which the requested output power is low, the control circuit not shown controls the bypass switch 51 to the ON state, and the signal path switches 53 and 56 and the bypass switch 58 to the OFF state.

In addition, the supply voltage is fed to the bypass amplifier 55, but its supply to the final stage amplifiers 54 and 57 and to the bypass amplifier 59 is stopped.

Accordingly, if it enters into the first operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the bypass amplifier 55 of the first path.

After that, the high-frequency signal amplified by the bypass amplifier 55 is output from the output terminal 17 of the amplifier circuit.

In the second operation mode in which the requested output power is high, the bypass switches 51 and 58 and the signal path switch 56 are controlled to the OFF state, and the signal path switch 53 is controlled to the ON state by the control circuit not shown.

In addition, the supply voltage is fed to the final stage amplifier 54, but its supply to the final stage amplifier 57 and to the bypass amplifiers 55 and 59 is stopped.

Accordingly, if it enters into the second operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the final stage amplifier 54 of the second path.

When the high-frequency signal amplified by the FETs 11 and 12 is supplied to the final stage amplifier 54, the high-frequency signal is amplified by the final stage amplifier 54, and the high-frequency signal after the amplification is output from the output terminal 17 of the amplifier circuit.

Second, a case will be described in which the modulating wave signal B is input through the input terminal 3 of the cascode amplifier.

In the first operation mode in which the requested output power is low, the control circuit not shown controls the bypass switch 58 to the ON state, and the bypass switch 51 and the signal path switches 53 and 56 to the OFF state.

In addition, the supply voltage is fed to the bypass amplifier 59, but its supply to the final stage amplifiers 54 and 57 and to the bypass amplifier 55 is stopped.

Accordingly, if it enters into the first operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the bypass amplifier 59 of the fourth path.

After that, the high-frequency signal amplified by the bypass amplifier 59 is output from the output terminal 27 of the amplifier circuit.

In the second operation mode in which the requested output power is high, the bypass switches 51 and 58 and the signal path switch 53 are controlled to the OFF state, and the signal path switch 56 is controlled to the ON state by the control circuit not shown.

In addition, the supply voltage is fed to the final stage amplifier 57, but its supply to the final stage amplifier 54 and to the bypass amplifiers 55 and 59 is stopped.

Accordingly, if it enters into the second operation mode when the FETs 1, 11, 2 and 12 are in the ON state, the high-frequency signal input through the input terminal 3 is amplified by the FETs 1 and 2, and the high-frequency signal after the amplification is supplied to the gate terminal of the FET 11.

When the high-frequency signal amplified by the FETs 1 and 2 is supplied to the gate terminal of the FET 11, the high-frequency signal is amplified by the FETs 11 and 12, and the high-frequency signal after the amplification is supplied to the final stage amplifier 57 of the third path.

When the high-frequency signal amplified by the FETs 11 and 12 is supplied to the final stage amplifier 57, the high-frequency signal is amplified by the final stage amplifier 57, and the high-frequency signal after the amplification is output from the output terminal 27 of the amplifier circuit.

The present embodiment 7 is configured in such a manner as to comprise the first to fourth paths across the drain terminal of the FET 12 and the output terminals 17 and 27 of the amplifier circuit, and to switch the path through which the high-frequency signal passes in accordance with the input modulating wave signal and the requested output power. Accordingly, it offers not only the same advantages as the foregoing embodiments 2-6, but also an advantage of being able to switch the output power of the high-frequency signal appropriately in response to the plurality of modulating wave signals.

Although a configuration is shown here in which the first path and fourth path are each comprised of the series circuit of the bypass switch and the bypass amplifier, a configuration is also possible in which they are comprised of the series circuit of the bypass switch and the matching circuit as shown in FIG. 8 of the foregoing embodiment 6.

In addition, although an example with the first to fourth paths is shown here, it can comprise a greater number of paths. In that case, it can handle more operation modes and modulating wave signals.

In addition, as for the voltages supplied from the voltage setting circuit 80 to the FETs 1 and 11, they may be equal or different, or can be varied in accordance with the operation modes.

Although the present embodiment 7 shows the cascode amplifier having two FETs connected in cascode, transistors connected in cascode are not limited to FETs, but can be bipolar transistors connected in cascode, for example.

In this case, replacing the gate widths of the FETs by the emitter areas of the transistors enables achieving the same advantages as the amplifier circuit of FIG. 5 and FIG. 6.

In addition, both or one of the final stage amplifiers 54 and 57 can be comprised of the cascode amplifier as shown in FIG. 7.

### Embodiment 8

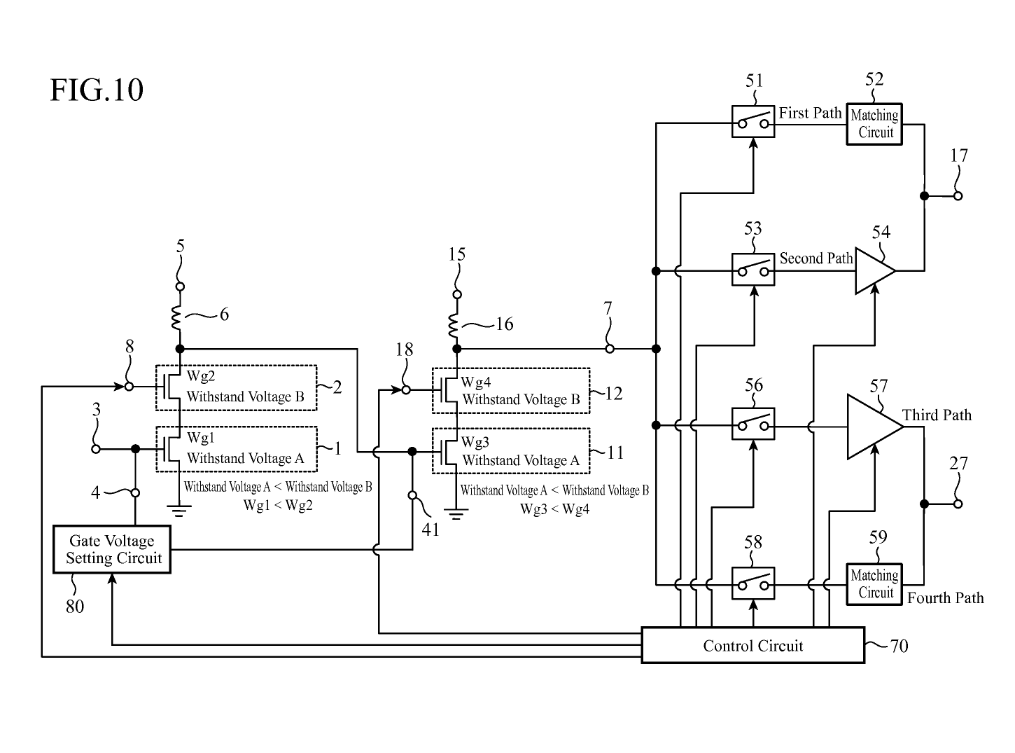

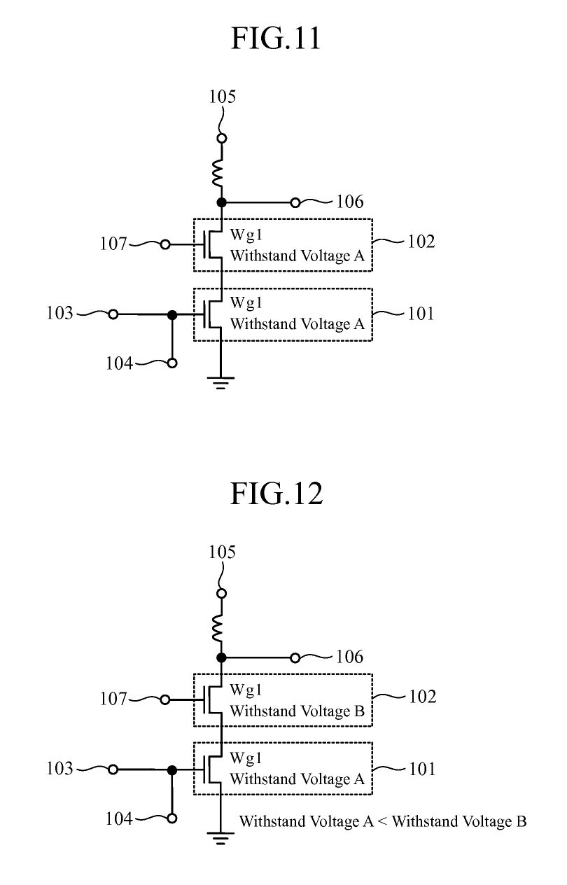

FIG. 10 is a diagram showing a configuration of an amplifier circuit of an embodiment 8 in accordance with the present invention. In FIG. 10, since the same reference numerals as those of FIG. 8 and FIG. 9 designate the same or like components, their description will be omitted.

FIG. 10 shows an amplifier circuit having two cascode amplifiers connected in series. The number of stages of the cascode amplifiers, however, is not limited to a specific number, but can be any desired number of stages.

The cascode amplifier increases its saturation power with an increase of the gate voltages of FETs 2 and 12, and reduces its saturation power with a reduction of the gate voltages of the FETs 2 and 12.

The control circuit 70 of the present embodiment 8 has a function of varying the gate voltages of the FETs 2 and 12 of the cascode amplifiers in accordance with the input modulating wave signal and the requested output power. Accordingly, it can deal with the case where different saturation powers are requested for the cascode amplifiers without changing the size of the FETs.

The control circuit 70 delivers the control signals in such a manner as to perform the same operations as in the foregoing embodiment 7 in accordance with the modulation scheme and the requested output power.

Furthermore, the control circuit 70 varies the saturation powers of the cascode amplifiers by varying the gate voltages supplied to the FETs 2 and 12 in accordance with the modulation scheme. Usually, the amplifier before the final stage amplifier (in this case, the cascode amplifier) maintains the linearity by operating at the output power with a sufficient backoff from the saturation power. For this reason, as the saturation power of the cascode amplifier increases, the amplifier circuit can increase the output power by that amount in the state of maintaining the backoff.

For example, consider the second operation mode in which the requested output power is high for two modulating wave signals X and Y.

It is assumed here that the requested output power is PX (dBm) for the modulating wave signal X, and the requested output power is PY (dBm) for the modulating wave signal Y (PY>PX).

In this case, if the modulating wave signal X is input through the input terminal 3, it passes through the second path and is output from the output terminal 17, whereas if the modulating wave signal Y is input through the input terminal 3, it passes through the third path and is output from the output terminal 27.

When the gains of the final stage amplifiers 54 and 57 are both GH, the control circuit 70 controls the power output from the output terminal 7 of the cascode amplifier in such a manner that it varies in conformity with the modulation scheme by the amount corresponding to the difference ΔPYX (=PY−PX) between the power PX (dBm) output from the output terminal 17 of the amplifier circuit and the power PY (dBm) output from the output terminal 27 of the amplifier circuit.

More specifically, to increase the saturation power of the cascode amplifiers, when the modulating wave signal Y is input, the control circuit 70 sets the gate voltages supplied to the FETs 2 and 12 greater than the gate voltages supplied to the FETs 2 and 12 when the modulating wave signal X is input, thereby increasing the output power from the output terminal 7 of the cascode amplifier.

This enables the plurality of modulation schemes to output desired power without altering the size of the FETs.

Furthermore, the control circuit 70 tries to vary the saturation powers of the cascode amplifiers by varying the gate voltages supplied to the FETs 2 and 12 in conformity with the operation mode.

For example, in the first operation mode and in the second operation mode, assume that the requested output power is PL (dBm) in the first operation mode and PH (dBm) in the second operation mode (here, PH>PL).

At this time, in the first operation mode, when the modulating wave signal is input through the input terminal 3, it passes through the first path and is output from the output terminal 17, whereas in the second operation mode, it passes through the second path and is output from the output terminal 17.

The control circuit 70 controls the power output from the output terminal 7 of the cascode amplifier in such a manner that it varies in accordance with relationships between the difference ΔPHL (=PH−PL) and the gain GH of the final stage amplifiers 54 and 57, where ΔPHL (=PH−PL) is the difference between the power PL (dBm) output from the output terminal 17 of the amplifier circuit in the first operation mode and the power PH (dBm) output from the output terminal 17 of the amplifier circuit in the second operation mode.

More specifically, when ΔPHL>GH, since it is necessary to make the power output from the output terminal 7 of the cascode amplifier in the second operation mode higher than the power output from the output terminal 7 of the cascode amplifier in the first operation mode, the control circuit 70 makes the gate voltages supplied to the FETs 2 and 12 in the second operation mode higher than the gate voltages supplied to the FETs 2 and 12 in the first operation mode.

In contrast with this, when ΔPHL<GH, since it is necessary to make the power output from the output terminal 7 of the cascode amplifier in the first operation mode higher than the power output from the output terminal 7 of the cascode amplifier in the second operation mode, the control circuit 70 makes the gate voltages supplied to the FETs 2 and 12 in the first operation mode higher than the gate voltages supplied to the FETs 2 and 12 in the second operation mode.

This enables the plurality of operation modes to output desired power without altering the size of the FETs.

The present embodiment 8 is configured in such a manner that it comprises the first to fourth paths across the drain terminal of the FET 12 and the output terminals 17 and 27 of the amplifier circuit, and that it switches the path through which the high-frequency signal passes and varies the gate voltages of the FETs 2 and 12 in accordance with the input modulating wave signal and the requested output power. Accordingly, it offers not only the same advantages as the foregoing embodiments 2-7, but also an advantage of being able to switch the output power of the high-frequency signal appropriately in response to the plurality of modulating wave signals whose requested output powers differ from each other.

Although a configuration is shown here in which the first path and fourth path are each comprised of the series circuit of the bypass switch and the bypass amplifier, a configuration is also possible in which they are comprised of the series circuit of the bypass switch and the matching circuit as shown in FIG. 8 of the foregoing embodiment 6.

In addition, although an example with the first to fourth paths is shown here, it can comprise a greater number of paths. In that case, it can handle more operation modes and modulating wave signals.

In addition, as for the voltages supplied from the voltage setting circuit 80 to the FETs 1 and 11, they may be equal or different, or can be varied in accordance with the operation modes.

Although the present embodiment 8 shows the cascode amplifier having two FETs connected in cascode, transistors connected in cascode are not limited to FETs, but can be bipolar transistors connected in cascode, for example.

In this case, replacing the gate widths of the FETs by the emitter areas of the transistors enables achieving the same advantages as the amplifier circuit of FIG. 5.

In addition, both or one of the final stage amplifiers 54 and 57 can be comprised of the cascode amplifier as shown in FIG. 7.

Incidentally, it is to be understood that a free combination of the individual embodiments, variations of any components of the individual embodiments or removal of any components of the individual embodiments is possible within the scope of the present invention.

### INDUSTRIAL APPLICABILITY

A cascode amplifier and an amplifier circuit in accordance with the present invention are suitable for applications that must downsize and increase gain.

### DESCRIPTION OF REFERENCE SYMBOLS

1 FET (first transistor); 2 FET (second transistor); 3 input terminal of cascode amplifier; 4 gate voltage terminal; 5 supply voltage terminal; 6 inductor; 7 output terminal of cascode amplifier; 8 gate voltage terminal; 11 FET (first transistor); 12 FET (second transistor); 14 gate voltage terminal; 15 supply voltage terminal; 16 inductor; 17 output terminal of amplifier circuit; 18 gate voltage terminal; 21 FET (first transistor); 22 FET (second transistor); 24 gate voltage terminal; 25 supply voltage terminal; 26 inductor; 27 output terminal of amplifier circuit; 28 gate voltage terminal; 31 FET (first transistor); 41 FET (first transistor) ; 51 bypass switch; 52 matching circuit; 53 signal path switch; 54 final stage amplifier; 55 bypass amplifier; 56 signal path switch; 57 final stage amplifier; 58 bypass switch; 59 bypass amplifier; 61 FET; 62 FET; 64 gate voltage terminal; 65 supply voltage terminal; 66 inductor; 68 gate voltage terminal; 70 control circuit; 80 gate voltage setting circuit (voltage setting circuit); 101, 102 transistor; 103 input terminal of cascode amplifier; 104 gate voltage terminal; 105 supply voltage terminal; 106 output terminal of cascode amplifier; 107 gate voltage terminal.

1-6. (canceled)

7. An amplifier circuit comprising N (N is a natural number not less than two) stages of cascode amplifiers connected in series, wherein the cascode amplifier includes a first transistor and a second transistor connected in cascode, the first transistor having its source terminal or emitter terminal grounded and the second transistor having its source terminal or emitter terminal connected to the drain terminal or collector terminal of the first transistor, and wherein
in at least one of the cascode amplifiers, a gate width or emitter area of the first transistor is smaller than a gate width or emitter area of the second transistor; and
the gate width or emitter area of the first transistor at least at a Pth stage (P is a natural number of 2≦P≦N) is equal to the gate width or emitter area of the second transistor at a (P-1)th stage.

8. The amplifier circuit according to claim 7, further comprising:
L (L is a natural number) final stage amplifiers connected in parallel at a post-stage of at least one or more stages of the cascode amplifiers; and
bypass paths connected in parallel with the L final stage amplifiers.

9. The amplifier circuit according to claim 8, wherein the final stage amplifiers are comprised of a cascode amplifier.

10. The amplifier circuit according to claim 8, wherein the bypass paths are comprised of a series circuit of a bypass switch and a matching circuit.

11. The amplifier circuit according to claim 8, wherein the bypass paths are comprised of a series circuit of a bypass switch and a bypass amplifier.

12. The amplifier circuit according to claim 11, wherein the bypass amplifier is comprised of a cascode amplifier.

13. The amplifier circuit according to claim 8, further comprising:
signal path switches connected between the cascode amplifier and the L final stage amplifiers, wherein the bypass paths are comprised of a series circuit of a bypass switch and a matching circuit or a bypass amplifier; and
a control circuit that controls, in a first operation mode in which requested output power is first power, the bypass switch to an ON state and the signal path switches to an OFF state, and controls, in a second operation mode in which the requested output power is higher than the first power, the bypass switch to an OFF state and the signal path switch to an ON state.

14. The amplifier circuit according to claim 13, wherein
the control circuit switches the gate voltages of the first transistor and of the second transistors constituting the cascode amplifiers in response to a signal amplified by the cascode amplifiers.
